(19) United States
(12) Patent Application Publication
(10) Pub. No.: US 2025/0070642 A1
(43) Pub. Date: Feb. 27, 2025

(54) DRIVE CIRCUIT AND METHOD FOR CONTROLLING DRIVE CIRCUIT

(71) Applicant: Hitachi Astemo, Ltd., Hitachinaka-shi, Ibaraki (JP)

(72) Inventors: Yoshiaki MIZUHASHI, Hitachinaka-shi, Ibaraki (JP); Masahiro DOI, Hitachinaka-shi, Ibaraki (JP); Mitsuhiro IWASAKI, Hitachinaka-shi, Ibaraki (JP)

(73) Assignee: Hitachi Astemo, Ltd., Hitachinaka-shi, Ibaraki (JP)

(21) Appl. No.: 18/719,158

(22) PCT Filed: Dec. 14, 2021
(86) PCT No.: PCT/JP2021/046015

§ 371 Date: Jun. 12, 2024

(51) Int. Cl. H02M 1/08; H02M 1/00; H02P 27/08; H03K 17/16

(52) U.S. Cl. CPC H02M 1/08; H02M 1/0054; H03K 17/162; H03K 17/168; H02P 27/08

(57) ABSTRACT

In a drive circuit of a voltage-driven power semiconductor switching element, a drive circuit capable of performing efficient switching control according to a drive condition with a relatively simple configuration is provided. The drive circuit includes the voltage-driven switching element, an on-circuit that injects a charge into a gate of the voltage-driven switching element in response to a drive signal, and an off-circuit that extracts the charge from the gate of the voltage-driven switching element in response to a drive signal. In the drive circuit, the injection of the charge into the gate of the voltage-driven switching element or the extraction of the charge from the gate by pulse driving of the on-circuit or the off-circuit, and switching time of the voltage-driven switching element is controlled.

### TECHNICAL FIELD

The present invention relates to a configuration of a drive circuit of a voltage-driven power semiconductor switching element and a control method thereof, and particularly relates to an effective technique applied to the drive circuit of the voltage-driven power semiconductor switching element used in an in-vehicle power conversion device that is required to have power saving and high reliability.

### BACKGROUND ART

In a voltage-driven power semiconductor used in a power conversion device, an IGBT, a SiCMOSFET, or the like is used, and a high withstand voltage and a large current have been advanced in recent years. These power conversion devices are also used in electrically powered vehicles, and are used for the purpose of generating an alternating current driving a motor from a direct current supplied from a battery.

In such a field, for the purpose of increasing use efficiency of the battery, a switching loss is required to be reduced in order to prevent loss due to heat generation in the power conversion device. In order to solve such a problem, for example, a technique such as PTL 1 in which switching is performed such that input resistors of the IGBT are switched has been developed.

### CITATION LIST

### Patent Literature

PTL 1: JP H9-46201 A

### SUMMARY OF INVENTION

### Technical Problem

However, in the technique of PTL 1, it is necessary to prepare a plurality of resistors and switching elements in order to switch the operated driving circuit, which causes problems such as an increase in a mounting area and a number of components.

In addition, the switching of the drive circuit can be changed only in the prepared drive circuit, and the switching timing is also fixed, so that efficient switching cannot be performed depending on conditions, and in the worst case, there is a possibility that the voltage-driven power semiconductor is destroyed.

An object of the present invention is to provide a drive circuit capable of performing efficient switching control according to a drive condition with a relatively simple configuration and a control method thereof in the drive circuit of the voltage-driven power semiconductor switching element.

### Solution to Problem

In order to solve the above problems, the present invention includes a voltage-driven switching element, an on-circuit that injects a charge into a gate of the voltage-driven switching element according to a drive signal, and an off-circuit that extracts the charge from the gate of the voltage-driven switching element according to the drive signal, in which the injection of the charge into the gate of the voltage-driven switching element or the extraction of the charge from the gate is performed by pulse driving of the on-circuit or the off-circuit, and a switching time of the voltage-driven switching element is controlled.

Furthermore, the present invention is a method for controlling a drive circuit that drives and controls a voltage-driven switching element, the method includes injecting a charge into a gate of the voltage-driven switching element or extracting the charge from the gate by pulse driving of an on-circuit or an off-circuit of the voltage-driven switching element, and controlling a switching time of the voltage-driven switching element.

### Advantageous Effects of Invention

According to the present invention, the drive circuit capable of performing the efficient switching control according to the drive condition with the relatively simple configuration and the control method thereof can be implemented in the drive circuit of the voltage-driven power semiconductor switching element.

Accordingly, it is possible to reduce the switching loss of the voltage-driven power semiconductor switching element, and it is possible to contribute to improvement in efficiency and reliability of the power conversion device.

Problems, configurations, and effects other than those described above will be clarified by the following description of embodiments.

### BRIEF DESCRIPTION OF DRAWINGS

FIG. 1 is a schematic configuration diagram illustrating a power conversion device according to a first embodiment of the present invention.

FIG. 2 is a view illustrating a control system for one system of a voltage-driven switching element in FIG. 1.

FIG. 3 is a view illustrating a loss in the voltage-driven switching element.

FIG. 4 is a view illustrating a relationship between a slew rate and a surge in the voltage-driven switching element.

FIG. 5 is a view illustrating a relationship among a number of times, the slew rate, and the surge for injecting a charge with a pulse into a control terminal of the voltage-driven switching element.

FIG. 6 is a view illustrating a relationship among a pulse width, the slew rate, and the surge for injecting the charge into the control terminal of the voltage-driven switching element.

FIG. 7 is a configuration diagram illustrating a driver circuit according to a second embodiment of the present invention.

FIG. 8 is a view illustrating a relationship between a control terminal signal pattern, the slew rate, and the surge in FIG. 7.

FIG. 9 is a configuration diagram illustrating a driver circuit according to a third embodiment of the present invention.

### DESCRIPTION OF EMBODIMENTS

Hereinafter, embodiments of the present invention will be described with reference to the drawings. In the drawings, the same components are denoted by the same reference numerals, and the detailed description of overlapping components is omitted.

### First Embodiment

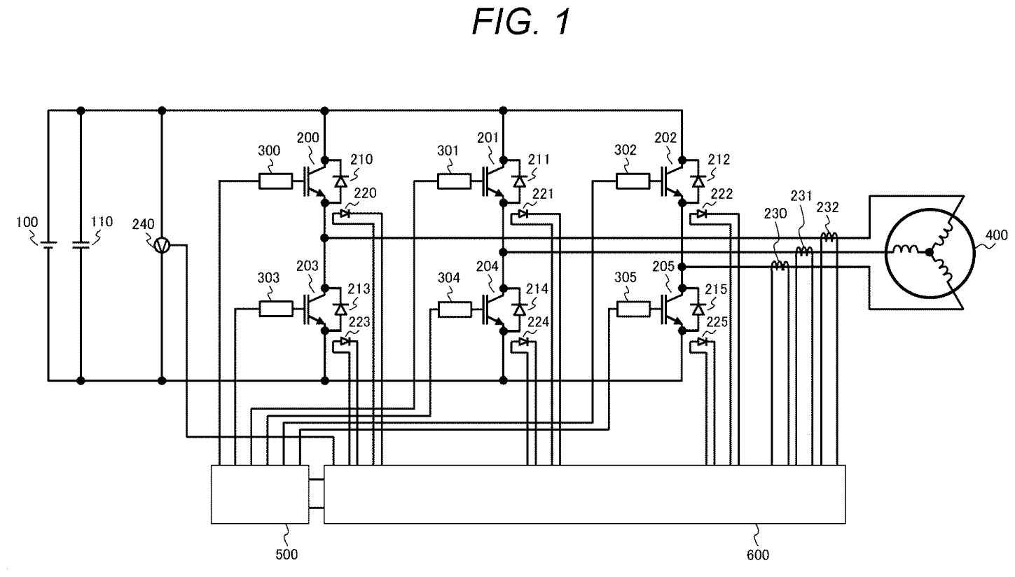

A configuration of a drive circuit according to a first embodiment of the present invention and a control method thereof will be described with reference to FIGS. 1 to 6.

FIG. 1 is a schematic configuration diagram illustrating a power conversion device between a battery and a motor generator, the power conversion device being configured using a drive circuit of the first embodiment.

A sign 100 denotes a battery, and plays a role of supplying a DC voltage serving as a source of power in the power conversion device or storing the power generated by a motor generator 400 described later.

A sign 110 denotes a capacitor that supplies the power in an instantaneous voltage drop when the motor generator 400 is driven and stores the power when the motor generator 400 generates the power. In addition, noise generated in switching of voltage-driven switching element 200 to 205 described later is reduced by charge and discharge.

Signs 200 to 205 denote voltage-driven switching elements such as an insulated gate bipolar transistor (IGBT) or an SiC metal oxide semiconductor field effect transistor (MOSFET), but is not limited thereto. The control terminals of the voltage-driven switching element 200 to 205 are charged and discharged to perform switching operation, and power conversion is performed.

Signs 210 to 215 denote diodes connected in anti-parallel to the voltage-driven switching elements 200 to 205, and are used for circulating current. Although the diodes are used as a single body, the diodes may be configured based on parasitic elements of the voltage-driven switching elements 200 to 205.

Signs 220 to 225 denote temperature sensors, and the diodes acquire temperature information of the voltage-driven switching elements 200 to 205 and outputs the temperature information to a control circuit 600 described later. For example, a constant current is passed through the diode 210 to 215, and the measurement is performed by a voltage drop amount.

FIG. 1 illustrates a configuration in which each one of the temperature sensors 220 to 225 is disposed for each of the voltage-driven switching elements 200 to 205. However, for example, as in the voltage-driven switching elements 200 and 203, the voltage-driven switching elements 201 and 204, and the voltage-driven switching elements 202 and 205, one temperature sensor may be disposed for each combination as long as there is no difference in temperature such that two voltage-driven switching elements are packaged together in an upper arm and a lower arm. Furthermore, as long as there is no temperature deviation, one temperature sensor may be disposed for the voltage-driven switching elements 200 to 205.

Signs 230 to 232 denote a current sensor that acquires information about an amount of current flowing through each of the three-phase (U, V, W) lines connected to the motor generator 400 and outputs the information to the control circuit 600. For the current sensor 230 to 232, a detection method in which a magnetic field by a Hall element is used may be adopted, a detection method in which a shunt resistor is used may be adopted, or other methods may be adopted.

A sign 240 denotes a voltage sensor that acquires voltage information about the battery 100 and the capacitor 110 and outputs the voltage information to the control circuit 600.

Signs 300 to 305 denote a resistor, and the resistors limit the amounts of current injected into the control terminals of the voltage-driven switching elements 200 to 205 or the extracted current amounts. In FIG. 1, the resistor 300 to 305 have a configuration in which one resistor is disposed for each of the voltage-driven switching elements 200 to 205, but there may be a configuration in which a plurality of resistors are disposed.

A sign 400 denotes, for example, a motor generator that is a synchronous machine or an induction machine, and is a device that is driven as a motor when power is supplied and acts as a generator when rotational force is applied to a rotation shaft. Because the operation of the motor generator changes depending on the operation method, the motor generator is described in the present invention.

In FIG. 1, a three-phase power conversion device that is driven using six voltage-driven switching elements 200 to 205 and six diodes 210 to 215 is taken as an example. However, the present invention is not limited thereto, and the number may be increased or decreased according to the configuration.

A sign 500 denotes a driver circuit that drives the voltage-driven switching element 200 to 205 through the resistor 300 to 305.

A sign 600 denotes a control circuit that controls the driver circuit 500 using each piece of information about the temperature sensor 220 to 225, the current sensor 230 to 232, and the voltage sensor 240, and operation instruction information for the motor generator 400 from a higher-level control unit (not illustrated).

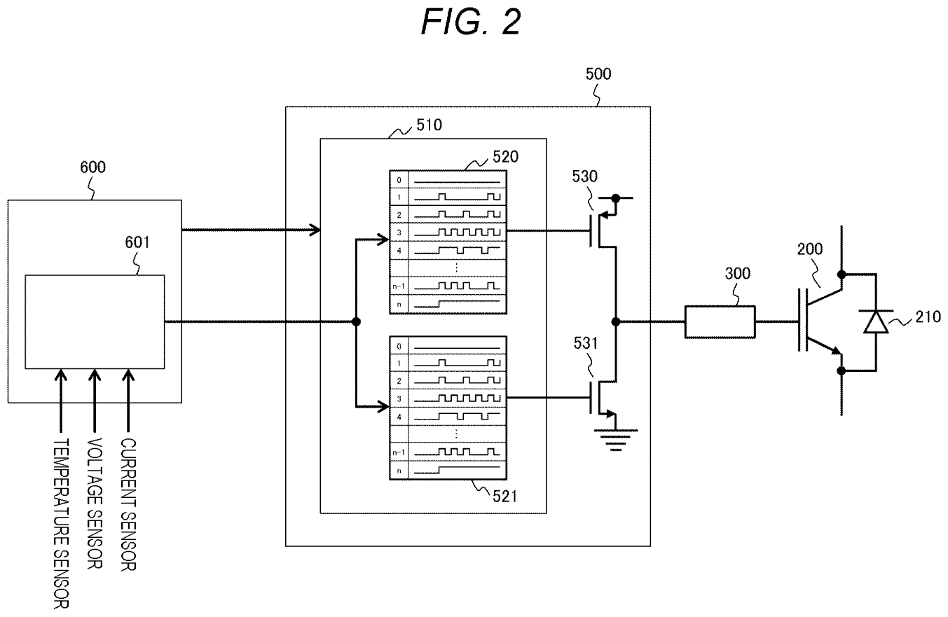

The operations of the driver circuit 500 and the control circuit 600 will be described in detail with reference to FIG. 2. FIG. 2 is a view illustrating a control system for one system driving the voltage-driven switching element 200.

The driver circuit 500 includes a gate control pulse generation unit 510, a drive circuit 530 that injects a charge into the control terminal of the voltage-driven switching element 200 through the resistor 300, and a drive circuit 531 that extracts the charge from the control terminal of the voltage-driven switching element 200 through the resistor 300.

In the gate control pulse generation unit 510, a table setting what type of pulse is generated to perform the charge injection or the charge extraction during switching of the voltage-driven switching element 200 is previously stored as a gate control pulse table 520 for the charge injection and a gate control pulse table 521 for the charge extraction.

The drive circuit 530 and the drive circuit 531 operate based on these tables, and the charge is injected as the pulse to the control terminal of the voltage-driven switching element 200 through the resistor 300 according to the gate control pulse table 520, and similarly, the charge is extracted as the pulse according to the gate control pulse table 521.

In the gate control pulse tables 520 and 521, a plurality of pulse patterns performing the switching of the voltage-driven switching element 200 are held, and which pulse pattern to use is selected by a signal instructed from the control circuit 600.

In these gate control pulse tables, a frequency of the pulse, time of the pulse, and a delay time from the switching instruction of the voltage-driven switching element 200 from the control circuit 600 to the first pulse generation may be held, or a generated pulse waveform itself may be held. In addition, there is no reason why the generated pulses also have to be equal, and there is no problem even with pulses at non-equal intervals.

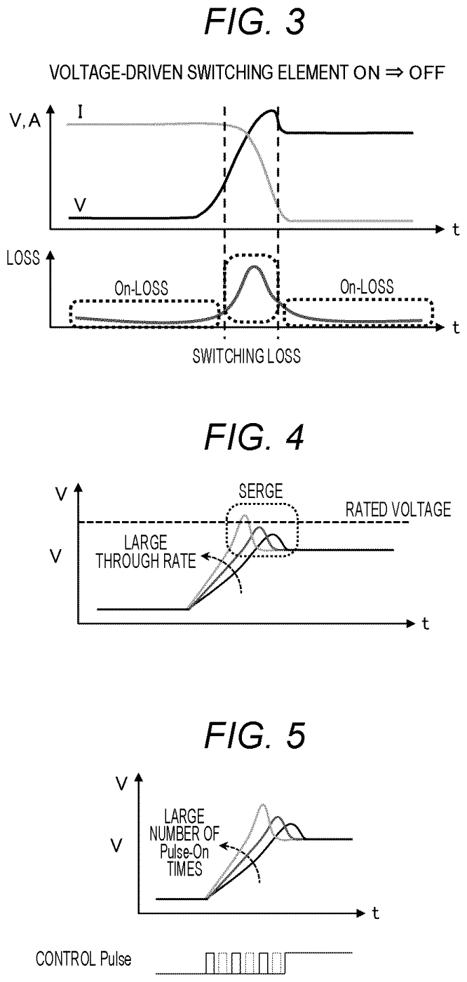

FIG. 3 illustrates loss in the voltage-driven switching element. FIG. 4 illustrates a relationship between a slew rate and a surge in the voltage-driven switching element.

In general, the loss in the voltage-driven switching element used in the power conversion device is divided into an on-loss and a switching loss as illustrated in FIG. 3.

Because the on-loss is determined by a characteristic of the voltage-driven switching element, the loss cannot be reduced unless the characteristic is improved.

On the other hand, with respect to the switching loss, when the charge injected into the control terminal of the voltage-driven switching element or the extracted charge is increased to increase a switching through rate of the voltage-driven switching element, the time required for the switching can be shortened, and accordingly, the switching loss can be reduced.

However, as illustrated in FIG. 4, when the slew rate is increased, the surge amount also increases at the same time, and eventually exceeds the rated voltage that can be applied to the voltage-driven switching element, which may lead to destruction of the switching element.

For this reason, in the conventional method, the resistance values of the resistors corresponding to the resistor 300 to 305 are determined as a fixed value such that the slew rate in which the surge does not exceed the voltage that may be applied to the voltage-driven switching element within a range of a use condition.

However, in this method, the slew rate cannot be changed although there is a margin for the rated voltage that may be applied to the voltage-driven switching element depending on an environmental condition.

Accordingly, in the first embodiment, as illustrated in FIG. 5, the slew rate is controlled by changing the number of pulses injecting the charge into the control terminal of the voltage-driven switching element 200 through the resistor 300. The slew rate becomes steep when the number of times of injecting the charge into the control terminal by pulses is increased during the switching of the voltage-driven switching element 200, and the slew rate becomes gentle when the number of times is decreased. This is selected from waveforms registered in the gate control pulse tables 520 and 521 and performed.

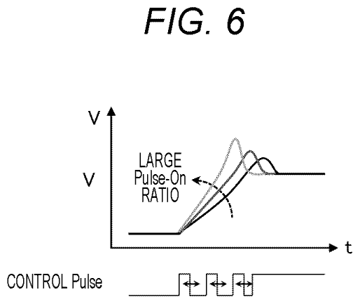

Instead of a pulse frequency modulation (PFM) method in which the slew rate of the switching of the voltage-driven switching element 200 is controlled by the number of pulses as illustrated in FIG. 5, a pulse width modulation (PWM) method in which the slew rate is controlled by a pulse width as illustrated in FIG. 6 may be used. In this case, the wider the pulse width, the higher the slew rate of the switching of the voltage-driven switching element 200.

In the conventional method, in order to perform the slew rate control, it is necessary to arrange pluralities of drive circuits corresponding to the drive circuit 530 and the drive circuit 531 and elements corresponding to the resistor 300, and switch a driving circuit or change the number of driving circuits.

However, the slew rate can be changed only in a maximum of 2ⁿ−1 stages even in the case where n systems are arranged, each physical size is large, and it is not realistic to arrange a large number of systems.

On the other hand, in the first embodiment, the slew rate can be controlled for stages of the PFM or the PWM by only one system of the drive circuit corresponding to the drive circuit 530 and the drive circuit 531 and the resistor 300, and the slew rate can be changed more efficiently.

Accordingly, the switching loss of the voltage-driven switching element 200 can be reduced, and DC power charged in the battery 100 can be more efficiently converted into three-phase AC power.

The waveforms registered in the gate control pulse tables 520 and 521 may not be the pulses at equal intervals.

For example, a waveform in which a pulse amount is increased or a duty ratio (Duty) of the pulse is increased to increase the slew rate at a beginning of a switching start of the voltage-driven switching element 200 while the pulse amount is decreased or the duty ratio (Duty) of the pulse is decreased to decrease the slew rate at a latter half of the switching is registered, and the switching waveform is controlled, so that the surge generated during the switching may be prevented while the switching time is shortened to prevent the loss of the voltage-driven switching element 200.

Furthermore, a configuration in which both sets of the gate control pulse table 520 and the drive circuit 530, and the gate control pulse table 521 and the drive circuit 531 are operated during one switching from on to off or from off to on of the voltage-driven switching element 200 may be employed.

For example, during the switching from off to on of the voltage-driven switching element 200, the charge is injected into the control terminal of the voltage-driven switching element 200 through the resistor 300 using the gate control pulse table 520 and the drive circuit 530 to perform the switching at the beginning of the switching, and a part of the charge is extracted from the control terminal of the voltage-driven switching element 200 through the resistor 300 using the gate control pulse table 521 and the drive circuit 531 to lower the slew rate of the switching to prevent the surge in the latter half of the switching in the latter half of the switching, and the drive circuit 530 may be turned on and fixed again after the switching is completed.

When such processing is performed, the switching waveform can be controlled with a higher degree of freedom, the switching time can be shortened, the loss of the voltage-driven switching element 200 can be reduced, and the surge generated during the switching can be prevented.

The control circuit 600 includes a gate control selection unit 601. The gate control selection unit 601 outputs a signal selecting the waveform used in the gate control pulse tables 520 and 521 using each piece of information about the temperature sensor 220 to 225, the current sensor 230 to 232, and the voltage sensor 240.

For example, for the voltage sensor 240, the higher the voltage, the smaller the surge amount allowed within the rated voltage that may be applied to the voltage-driven switching element 200, so that a table with a low on ratio (the number of pulses is small in the case of the PFM, and the duty is low in the case of the PWM) is selected.

For the temperature sensor 220 to 225, for example, the influence of the surge becomes significant at a low temperature in the case where the IGBT is used as the voltage-driven switching element 200, so that it may be determined that the temperature sensor having the lowest temperature among the temperature sensors 220 to 225 becomes critical, and the waveforms used in the gate control pulse tables 520 and 521 may be selected based on the information.

Similarly, the current sensor 230 to 232 can also be configured to select the waveforms used in the gate control pulse tables 520 and 521 based on the information from the current sensor 230 to 232.

In addition, although not illustrated, a signal selecting the waveform used in the gate control pulse tables 520 and 521 may be generated using information such as output request torque and a rotation speed in the motor generator 400 from a higher-level control unit and voltage applied to each phase of the motor generator 400.

For example, in the case where the output request torque in the motor generator 400 is large, because the increase in temperature is expected, it is possible to adopt a configuration in which a table having a higher on ratio is used when the waveforms used in the gate control pulse tables 520 and 521 are used. Similarly, even in the case where the rotation speed is high, because the further increase in temperature is expected, it is possible to adopt a configuration in which a table having a higher on ratio is used when the waveforms used in the gate control pulse tables 520 and 521 are selected.

In the case where the signal selecting the waveform used in the gate control pulse tables 520 and 521 is changed during the switching operation of the voltage-driven switching element 200, an unexpected pulse pattern is obtained, and the voltage exceeds a withstand voltage of the voltage-driven switching element 200, which may lead to breakdown. For this reason, it is desirable to perform control such that the voltage-driven switching element 200 is not destroyed by switching the signal selecting the waveform used in the gate control pulse tables 520 and 521 at timing at which the switching is not generated in synchronization with an on and off switching cycle of the voltage-driven switching element 200.

In addition, although the driver circuit 500 drives the voltage-driven switching element 200 to 205 through the resistor 300 to 305, when the signals selecting the waveforms used in the respective gate control pulse tables 520 and 521 for these voltage-driven switching element 200 to 205 are not switched at the same time, there is a possibility that a difference is generated in the switching between the voltage-driven switching elements 200 to 205 and the motor generator 400 cannot be controlled as expected.

In order to prevent this, the selection signals of the gate control pulse tables 520 and 521 are desirably controlled so as to be updated in synchronization for the upper and lower arm total of six phases of the voltage-driven switching element 200 to 205.

According to the configuration of the drive circuit and the control method thereof of the first embodiment described above, the efficient switching control of the voltage-driven power semiconductor switching element can be performed under various environmental conditions, and the efficient power conversion device can be provided.

### Second Embodiment

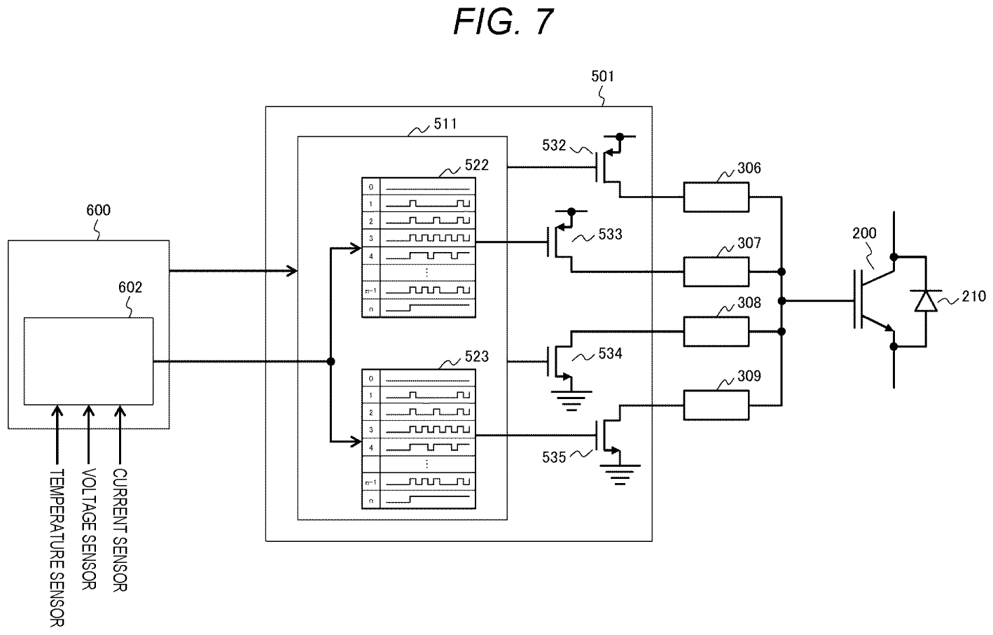

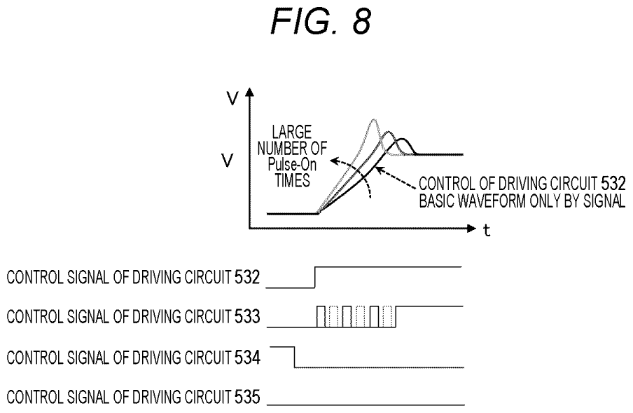

A configuration of a drive circuit according to a second embodiment of the present invention and a control method thereof will be described with reference to FIGS. 7 and 8.

FIG. 7 is a configuration diagram illustrating the driver circuit of the second embodiment, and illustrates a control system for one system of the voltage-driven switching element similarly to FIG. 2.

The configuration of the power conversion device is substantially the same as that of the first embodiment (FIG. 1), and the driver circuit 500 is replaced with a driver circuit 501, and each of the resistors 300 to 305 is replaced with four resistors 306 to 309. Four resistors 306 to 309 are connected to the control terminal of the voltage-driven switching element 200. Hereinafter, the description of the configuration and function already described in the first embodiment will be omitted.

The driver circuit 501 includes a gate control pulse generation unit 511 and incorporates gate control pulse tables 522 and 523.

The driver circuit 501 includes drive circuit 532, 534 in addition to the drive circuit 533, 535 controlled by the gate control pulse tables 522 and 523. Unlike the drive circuits 533, 535, the drive circuits 532, 534 are not controlled by the gate control pulse table, but are directly controlled by the gate control pulse generation unit 511.

The operations of the control circuit 600, the gate control pulse generation unit 511, the resistors 306 to 309, and the voltage-driven switching element 200 will be described with reference to FIG. 8. FIG. 8 is a view illustrating a relationship among the control terminal signal pattern, the slew rate, and the surge in FIG. 7.

When the control circuit 600 issues the instruction to control the switching of the voltage-driven switching element 200 from an off-state to an on-state, the gate control pulse generation unit 511 first turns off the control signal of the drive circuit 534 to perform the control such that a through current does not flow.

Thereafter, the control signal of the drive circuit 532 is turned on to inject the charge into the control terminal of the voltage-driven switching element 200. This is the basic (lowest slew rate) state when the voltage-driven switching element 200 is switched from the off-state to the on-state.

In addition, the gate control pulse generation unit 511 turns on the control signal of the drive circuit 532, and at the same time, the drive circuit 533 is driven by the waveform of the gate control pulse table 522 selected according to the gate control selection unit 602 of the control circuit 600, and the additional charge is injected into the control terminal of the voltage-driven switching element 200 through the resistor 307, and the slew rate is controlled.

Similarly to the first embodiment, the waveform selection of the gate control selection unit 602 is performed based on the information about the temperature sensor, the voltage sensor, the current sensor, and the like, and controlled such that the slew rate is high within the withstand voltage range of the voltage-driven switching element 200, and the loss of the voltage-driven switching element 200 is reduced, and the efficient power conversion processing is performed.

On the other hand, in the case of the instruction to control the switching of the voltage-driven switching element 200 from the on-state to the off-state, the operations of the drive circuit 532 and the drive circuit 534 are reversed, the charge of the control terminal of the voltage-driven switching element 200 is extracted through the resistor 308, the drive circuit 535 is operated by the waveform of the gate control pulse table 523 instead of the drive circuit 533, the charge of the control terminal of the voltage-driven switching element 200 is additionally extracted through the resistor 309, and the slew rate of the switching is controlled. Accordingly, the efficient power conversion processing is performed.

Unlike the first embodiment, in the second embodiment, two systems of the drive circuit that injects the charge and the drive circuit that extracts the charge are prepared, and the switching of the voltage-driven switching element 200 can be continued even when either one of the drive circuits does not operate.

For example, when the drive circuit 533 does not operate, the drive circuit 532 can perform the switching of the voltage-driven switching element 200 by injecting the charge through the resistor 306. In addition, for example, in the case where the drive circuit 534 does not operate, the drive circuit 535 is driven by selecting the waveform having the high duty ratio (Duty) or the large number of pulses are selected as the waveform of the gate control pulse table 523, and the charge is extracted through the resistor 309. Thereby, the switching of the voltage-driven switching element 200 can also be performed at the slew rate close to the slew rate when there is no problem. This makes it possible to provide the power conversion device having high robustness.

In the second embodiment, the configuration in which each one of the resistors 306 to 309 is disposed in each of the drive circuits 532 to 535 is adopted. However, even in a configuration in which one resistor is shared by the drive circuits 532 and 535 and one resistor is shared by the drive circuits 533 and 534, the same effect can be obtained. In addition, a configuration in which one resistor is shared by the drive circuit 532 to 535 can also be adopted.

### Third Embodiment

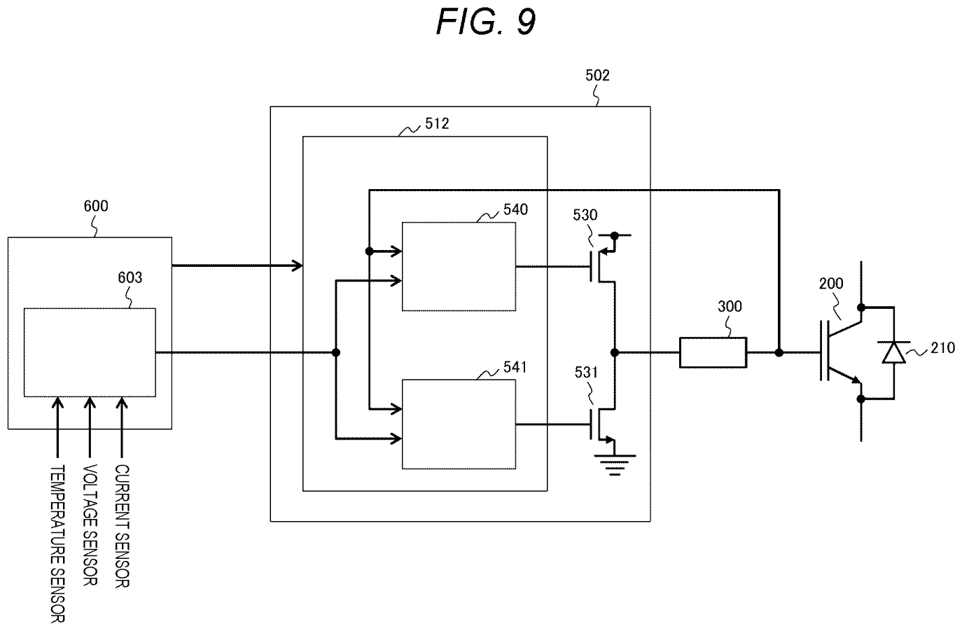

A configuration of a drive circuit according to a third embodiment of the present invention and a control method thereof will be described with reference to FIG. 9.

FIG. 9 is a configuration diagram illustrating a driver circuit of the present embodiment, and illustrates a control system for one system of the voltage-driven switching elements similarly to FIGS. 2 and 7.

The configuration of the power conversion device is substantially the same as that of the first embodiment (FIG. 1), and the driver circuit 500 is replaced with a driver circuit 502. However, the voltage of the control terminal of the voltage-driven switching element 200 is input to the driver circuit 502. Hereinafter, the description of the configuration and function already described in the first embodiment will be omitted.

A gate control pulse generation unit 512 includes gate control pulse generation units 540 and 541. The gate control pulse generation unit 540, 541 holds the relationship between the target voltage of the control terminal and time during the switching of the voltage-driven switching element 200.

This information can be rewritten by the gate control selection unit 603 of the control circuit 600 based on the information about the temperature sensor, the voltage sensor, the current sensor, and the like. In addition, the waveform controlling the drive circuits 530 and 531 can be output by the PWM or the PFM, and the voltage of the control terminal of the voltage-driven switching element 200 is input.

For example, in the case where the voltage-driven switching element 200 is switched from the off-state to the on-state, the target voltage in the time from the control instruction of the switching from the off-state to the on-state from the control circuit 600 is compared with the voltage of the control terminal of the voltage-driven switching element 200. In the case where the target voltage is low, the duty ratio (Duty) of the PWM is controlled to be increased or the number of pulses of the PFM is controlled to be increased, and the charge injection amount through the resistor 300 is increased. Conversely, in the case where the duty ratio is high, the duty ratio (Duty) of the PWM is controlled to be lowered or the number of pulses of the PFM is controlled to be reduced, the charge injection amount is lowered, and the slew rate of the voltage-driven switching element 200 is adjusted.

In the third embodiment, the control is performed using the voltage of the control terminal of the voltage-driven switching element 200, so that the slew rate of the switching of the voltage-driven switching element 200 can be more accurately controlled, the switching time can be shortened to reduce the loss of the voltage-driven switching element 200, and the surge generated at the time of switching can be suppressed.

In addition, the gate control pulse generation units 540, 541 also hold a threshold in the case where the voltage excessively fluctuates from the target voltage. In this case, the control may be performed so as to approach the target voltage by performing the injection or extraction of the charge from the control terminal of the voltage-driven switching element 200 by the drive circuit on the opposite side (for example, in the case of the switching from off to on, the drive circuit 530 relates to the switching, and the opposite side is the drive circuit 531) to that related to the switching of the voltage-driven switching element 200 in the drive circuit 530, 531 similarly to the first embodiment.

In each of the above embodiments, the drive circuit has been described as an example of the power conversion device that drives the motor generator 400. However, the present invention is not limited thereto, but can also be applied to on-vehicle an inverter circuit, an uninterruptible power supply device, a power conversion device of a train or a ship, an industrial power conversion device such as an electric motor of a factory facility, a power conversion device of a solar power generation system, a power conversion device of a home electric motor, and the like.

The present invention is not limited to the above-described embodiments, but includes various modifications. For example, the above-described embodiments have been described in detail for easy understanding of the present invention, and are not necessarily limited to those having all the described configurations. In addition, a part of the configuration of a certain embodiment can be replaced with the configuration of another embodiment, and the configuration of another embodiment can be added to the configuration of a certain embodiment. In addition, it is possible to add, delete, and replace other configurations for a part of the configuration of each embodiment.

### REFERENCE SIGNS LIST

100 battery
110 capacitor
200 to 205 voltage-driven switching element
210 to 215 diode
220 to 225 temperature sensor
230 to 232 current sensor
240 voltage sensor
300 to 309 resistor
400 motor generator
500 to 502 driver circuit
510 to 512 gate control pulse generation unit
520 to 523 gate control pulse table
530 to 535 drive circuit
540, 541 gate control pulse generation unit
600 control circuit
601 to 603 gate control selection unit

1. A drive circuit that controls switching time of a voltage-driven switching element, the drive circuit comprising:
the voltage-driven switching element;
an on-circuit that injects a charge into a gate of the voltage-driven switching element in response to a drive signal; and
an off-circuit that extracts the charge from the gate of the voltage-driven switching element in response to a drive signal,
wherein the injection of the charge into the gate of the voltage-driven switching element or the extraction of the charge from the gate by pulse driving of the on-circuit or the off-circuit, and switching time of the voltage-driven switching element is controlled.

2. The drive circuit according to claim 1, wherein a pulse pattern driving the on-circuit or the off-circuit is held as a table.

3. The drive circuit according to claim 2, wherein the pulse pattern is selected based on at least one of a temperature of the voltage-driven switching element, an amount of current flowing through the voltage-driven switching element, a DC voltage supplied to the voltage-driven switching element, and voltage of a terminal of the voltage-driven switching element.

4. The drive circuit according to claim 2, wherein the pulse pattern is updated in synchronization with a switching cycle of the voltage-driven switching element.

5. The drive circuit according to claim 4, wherein the drive circuit is used in a circuit that generates an alternating current having a number of phases of at least three phases.

6. The drive circuit according to claim 2, further comprising another on-circuit and another off-circuit that are different from the on-circuit and the off-circuit,
wherein the another on-circuit and off-circuit are turned on and off only once in a switching cycle of the voltage-driven switching element.

7. The drive circuit according to claim 2, wherein the pulse pattern is non-uniform.

8. The drive circuit according to claim 2, wherein a pulse pattern driving the on-circuit and a pulse pattern driving the off-circuit both exist during switching operation of the voltage-driven switching element.

9. The drive circuit according to claim 2, wherein the pulse pattern is selected based on torque output from a synchronous machine or an induction machine driven by the drive circuit.

10. The drive circuit according to claim 2, wherein the pulse pattern is selected based on a number of rotations output from a synchronous machine or an induction machine driven by the drive circuit.

11. The drive circuit according to claim 2, wherein a switching time of the voltage-driven switching element is changed by changing the pulse pattern.

12. The drive circuit according to claim 1, wherein the voltage-driven switching element mounted on the power conversion device is driven and controlled.

13. A method for controlling a drive circuit that drives and controls a voltage-driven switching element, the method comprising:
injecting a charge into a gate of the voltage-driven switching element or extracting the charge from the gate by pulse driving of an on-circuit or an off-circuit of the voltage-driven switching element; and
controlling a switching time of the voltage-driven switching element.

14. The method for controlling the drive circuit according to claim 13, wherein a pulse pattern driving the on-circuit or the off-circuit is held as a table.

15. The method for controlling the drive circuit according to claim 14, wherein the pulse pattern is selected based on at least one of a temperature of the voltage-driven switching element, an amount of current flowing through the voltage-driven switching element, a DC voltage supplied to the voltage-driven switching element, and a voltage of a terminal of the voltage-driven switching element.
